(19) United States
(12) Patent Application Publication
(10) Pub. No.: US 2017/0253990 A1
(43) Pub. Date: Sep. 7, 2017

(54) A METHOD FOR PRODUCING MONOCRYSTALLINE GALLIUM CONTAINING NITRIDE AND MONOCRYSTALLINE GALLIUM CONTAINING NITRIDE, PREPARED WITH THIS METHOD

(71) Applicant: AMMONO S.A. W UPADLOSCI LIKWIDACYJNEJ, Warszawa (PL)

(72) Inventors: Robert KUCHARSKI, Warszawa (PL); Marcin ZAJAC, Garwolin (PL); Dorota GRZYBOWSKA, Warszawa (PL); Weronika KOROLCZUK, Warszawa (PL)

(21) Appl. No.: 15/510,941

(22) PCT Filed: Sep. 9, 2015
(86) PCT No.: PCT/EP2015/070633

§ 371 Date: Mar. 13, 2017

(30) Foreign Application Priority Data
Sep. 11, 2014 (PL) P.409465

(51) Int. Cl. C30B 7/10; C30B 29/40; C01B 21/06; C30B 7/14

(52) U.S. Cl. CPC C30B 7/105; C30B 7/14; C30B 29/406; C01B 21/0632; C01P 2006/40; C01P 2002/52

(57) ABSTRACT

The present invention relates to a method for producing monocrystalline gallium containing nitride from a source material containing gallium in the environment of supercritical ammonia solvent with the addition of a mineralizer containing the element of Group I (IUPAC, 1989), wherein in an autoclave two temperature zones are generated, i.e. a dissolution zone with lower temperature containing the source material, and a crystallization zone located below it with higher temperature, containing at least one seed. At least two further components are introduced into the process environment, namely an oxygen getter in molar ratio to ammonia ranging from 0.0001 to 0.2, and an acceptor dopant in molar ratio to ammonia not higher than 0.1, said acceptor dopant being manganese, iron, vanadium or carbon, or a combination thereof. The invention also relates to a monocrystalline gallium containing nitride prepared by this method.

The subject of the invention is a method for producing monocrystalline gallium containing nitride from a source material containing gallium in the environment of supercritical ammonia solvent with the addition of a mineralizer containing the element of Group I (IUPAC, 1989), wherein in an autoclave two temperature zones are generated, i.e. the dissolution zone with lower temperature containing the source material, and the crystallization zone located below it with higher temperature, containing at least one seed, the dissolution process of the source material and crystallization of gallium containing nitride on at least one seed is carried out. The invention comprises also monocrystalline gallium containing nitride, prepared with this method.

From international patent application No. WO 02/101120 A2 the method for producing a bulk monocrystalline gallium containing nitride is known, in particular gallium nitride, GaN, by its re-crystallization in a supercritical ammonia solution containing the mineralizer. The document WO 02/101120 A2 describes in detail and comprehensively the construction of the reactor (high-pressure autoclave) used in the process, as well as the appropriate source material, seeds, mineralizer and the course of the temperature and pressure process. The key information disclosed in WO 02/101120 A2 is the fact that gallium nitride under these conditions possesses the negative temperature coefficient of solubility. This means that its solubility decreases with increasing temperature. Consequently, in an autoclave the source material is placed higher than the seed, and in the re-crystallization phase, the temperature kept in the seed zone is higher than the temperature in the zone containing the source material. The result of that ongoing process is the dissolution of the source material and the growth of the monocrystalline GaN on the seed. WO 02/101120 A2 does not mention the use of Group II metal (IUPAC, 1989), i.e. alkaline earths metal, particularly calcium as the addition to a mineralizer or as the mineralizer. Mg and Zn are listed as possible dopants. The electrical properties of nitride monocrystals obtained are not described.

Polish patent application No. P-357706 discloses a complex mineralizer, in the form of alkali metal and alkaline earths metal (e.g. calcium and magnesium are listed), used in a molar ratio from 1:500 to 1:5 in relation to the alkali metal. The application mentions the possibility of the material admixing, but it does not define the amount of specific dopants. The electrical properties of nitride monocrystals obtained are not described.

In turn, Polish patent application No. PL357700 discloses a complex mineralizer in the form of alkali metal and acceptor dopant (as example magnesium, zinc and cadmium were listed). No general amount of acceptor dopant in relation to the alkali metal or ammonia was given. In the execution example there the dopant in the form of magnesium was disclosed, used in a molar ratio of 0.05 to the main mineralizer, i.e. potassium. That application does not mention explicitly the use of calcium in combination with alkali metal as a mineralizer. The electrical properties of nitride monocrystals obtained are not described.

In international patent application No. WO 2004/053206 A1 the possibility of using a complex mineralizer of alkali metal and alkaline earths metal, preferably calcium or magnesium, or an alkali metal and an acceptor dopant, such as magnesium, zinc or cadmium, was again described. However, the simultaneous use of alkali metal, calcium and acceptor dopant was not disclosed. The electrical properties of nitride monocrystals obtained are not described.

International application No. WO 2005/122232 A1 discloses the use of 0.05 g of Zn or 0.02 g of Mg as an addition to the source material, which is metallic gallium. It means that under the process conditions the molar ratio of Zn or Mg to ammonia, which was used in the amount of 240 g, i.e. approximately 14 mol, is of the order of 10⁻⁵. In this way—according to WO 2005/122232 A1—a compensated (semi-insulating) material with a resistivity of about 10⁶ Ωcm is obtained. The application does not disclose the use of calcium (or other oxygen getter) as the addition to the mineralizer. The problem of the oxygen content in the crystals obtained is not considered.

Finally, European patent application No. EP 2267197 A1, in order to control the electrical properties of gallium nitride, and in particular to obtain a compensated (semi-insulating) material tells to use the mineralizer in the form of an alkali metal and at the same time acceptor dopant, specifically magnesium, zinc and manganese, in molar ratio of at least 0.0001 and the most preferably at least 0.001, in relation to ammonia. In the case of using zinc or magnesium, directly after the process a p-type material is obtained. Only through additional heat treatment (annealing) it becomes a semi-insulating material. In the case of using manganese—a semi-insulating material may be obtained directly after the process. The application does not disclose the use of calcium (or other oxygen getter) as addition to the mineralizer. The problem of the oxygen content in the crystals obtained is not considered.

In not published so far Polish patent application No. PL404149 it is suggested that in this method to obtain a gallium containing nitride, together with a mineralizer in the form of an alkali metal (metal of Group I, IUPAC 1989), in a molar ratio of from 1:200 to 1:2 in relation to ammonia, i.e. in accordance with the disclosure of the above mentioned patent applications, at least two further components should be introduced into the process environment, namely:
a) an oxygen getter in the form of calcium or a rare-earth element or a combination thereof, in the total molar ratio to ammonia from 0.0001 to 0.2, and
b) the acceptor dopants in the form of magnesium, zinc, cadmium, or beryllium, or combinations thereof, in the total mole ratio to ammonia of not more than 0.001.

Specifically, the application PL404149 discloses a method for producing monocrystalline gallium containing nitride from the source material containing gallium in the environment of supercritical ammonia solvent, with the addition of a mineralizer containing an element of Group I (IUPAC 1989), wherein in an autoclave two temperature zones are generated, i.e. the dissolution zone with lower temperature containing the source material, and the crystallization zone located below it with higher temperature, containing at least one seed, the dissolution process of the source material and crystallization of gallium containing nitride on at least one seed is carried out, which is characterized by introducing at least two additional components into the process environment, namely:
a) an oxygen getter in a molar ratio to ammonia from 0.0001 to 0.2.
b) an acceptor dopant in a molar ratio to ammonia of not more than 0.001.

As an oxygen getter in the application PL404149 calcium or a rare-earth element was disclosed, preferably gadolinium or yttrium, or a combination thereof, and as an acceptor dopant—magnesium, zinc, cadmium, or beryllium, or a combination thereof was disclosed.

GaN monocrystals obtained earlier without the above mentioned getter and acceptor dopant, are characterized by oxygen concentration (unintentionally introduced into the growth environment) at the level of 2×10¹⁹ cm⁻³ (F. Tuomisto, J.-M. Mäki, M. Zajac, Vacancy defects in bulk ammonothermal GaN crystals, J. Crystal Growth, 312, 2620 (2010)). The oxygen present in the crystal lattice acts as a donor providing free electrons with similar concentration—of the order of 2×10¹⁹ cm⁻³ or slightly lower (Tuomisto et al.), which makes the considered material highly conductive with the n-type conductivity. In turn, the introduction of the acceptor dopant only does not change the concentration of oxygen, but allows to change the conductivity type into p-type, and after an appropriate heat treatment it is possible to obtain a semi-insulating material with the resistivity of the order of 10¹¹ Ωcm (patent application EP 2267197 A1). At the same time, Mg acceptor is present therein at a level as high as up to approx. 4×10¹⁹ cm⁻³ (FIG. 2 in the application EP 2267197 A1). For the material of p-type conductivity, manipulating the concentration of Mg it is possible to control the resistivity and the concentration of free holes: for the molar ratio of Mg: NH₃=0.0001: the concentration of holes approx. 1×10¹⁸ cm⁻³, the resistivity of 9×10² Ωcm; for the molar ratio Mg: NH₃=0.00025: 5×10¹⁸ cm⁻³ and 8 Ωcm, respectively; for the ratio of Mg: NH₃=0.001: 1×10¹⁹ cm⁻³ and 1.7 Ωcm, respectively (Examples 1-4 in the application EP 2267197 A1).

It turned out that the simultaneous use of calcium or rare-earth element (or combinations thereof) and acceptor dopant (or acceptor dopants), in accordance with the disclosures of the application PL404149, gives an extremely favourable combination of the two phenomena. On the one hand, it allows to remove efficiently the oxygen from the resulting crystal, namely, by manipulating the amount of calcium it is possible to change continuously the oxygen concentration in the crystal in the range from about 10¹⁹ cm³ to about 10¹⁸ cm³. In the case of rare-earth elements—in a wide range of their content in the reaction environment—the monocrystal of low oxygen concentration of about 10¹⁸ cm³ and below is obtained. On the other hand, acceptor dopants, which can be incorporated very efficiently into the resulting monocrystal, compensate the unintentional donors (oxygen), so it is possible to control the electric properties of the crystal. It turns out that by introducing oxygen getters and acceptor dopants into the process environment at the same time and manipulating their composition (mutual proportions) and type it is possible to obtain the monocrystals of GaN with desired electric parameters (p-type, n-type, semi-insulating (compensated) material), but of higher purity, i.e. lower concentrations of oxygen and acceptor than those given in EP 2267197 A1. In particular, to obtain GaN monocrystals of similar electric parameters, as in the mentioned patent application, the acceptor dopant is used in the mole ratio (to ammonia) by an order or two orders of magnitude lower than in EP 2267197 A1. In a particular case, a material, which is perfectly compensated by the acceptors with a very high electric resistivity, which is higher than 10⁶ Ωcm, is obtained.

In the course of further research it turned out unexpectedly that it is particularly profitable to use specific, carefully selected elements as acceptor dopant, namely manganese (Mn), iron (Fe), vanadium (V) or carbon (C), in suitable amounts, which allows to obtain a material with even higher desired parameters, i.e. in particular with the electric resistivity, even exceeding 10¹⁰ Ωcm, at the same time with a very low content of oxygen. These dopants are deep acceptor centers, effectively capturing and trapping the carriers, which leads to a high resistivity of the obtained GaN crystals. The application PL404149 does not disclose manganese, iron, vanadium or carbon as possible acceptor dopants, neither discloses a gallium containing nitride with such high electric resistivity.

Therefore, the purpose of the present invention is to propose a method for producing monocrystalline gallium containing nitride with reduced oxygen content and improved electric properties. Another subject of the invention is to provide such nitride.

According to the invention, a method for producing monocrystalline gallium containing nitride from the source material containing gallium in the environment of supercritical ammonia solvent, with the addition of a mineralizer containing an element of Group I (IUPAC 1989), wherein in an autoclave two temperature zones are generated, i.e. the dissolution zone with lower temperature containing the source material, and the crystallization zone located below it with higher temperature, containing at least one seed, the dissolution process of the source material and crystallization of gallium containing nitride on at least one seed is carried out, wherein at least two additional components are introduced into the process environment, namely:
a) an oxygen getter in a molar ratio to ammonia from 0.0001 to 0.2.
b) an acceptor dopant in a molar ratio to ammonia of not more than 0.1.

is characterized in that the acceptor dopant constitutes manganese, iron, vanadium or carbon, or a combination thereof.

Preferably, the acceptor dopant is manganese in a molar ratio to ammonia from 0.000001 to 0.001, more preferably from 0.000005 to 0.0005, the most preferably from 0.00001 to 0.0001.

Alternatively, preferably, the acceptor dopant is iron in a molar ratio to ammonia from 0.000001 to 0.01, more preferably from 0.00005 to 0.005, the most preferably from 0.0001 to 0.001.

Alternatively, preferably, the acceptor dopant is vanadium in a molar ratio to ammonia from 0.000001 to 0.1, more preferably from 0.0005 to 0.05, the most preferably from 0.001 to 0.01.

Alternatively, preferably, the acceptor dopant is carbon in a molar ratio to ammonia from 0.000001 to 0.1, more preferably from 0.00005 to 0.05, the most preferably from 0.0001 to 0.01.

Preferably, the oxygen getter is calcium or a rare-earth element, preferably gadolinium or yttrium, or a combination thereof.

Preferably, the oxygen getter and acceptor dopant is introduced in the form of the element, i.e. of the metal or as a compound, preferably from the group comprising azides, amides, imides, amide-imides and hydrides, wherein the components are introduced separately or combined and in the latter case the mixtures of elements or compounds, intermetallic compounds or alloys are used.

Preferably, the oxygen getter and/or acceptor dopant are introduced into the process environment with a mineralizer.

The above mentioned individual components, according to the present invention may be introduced into the process environment in the elemental form (a metal), as well as various compounds such as, for example azides, amides, imides, amide-imides and hydrides, etc. These ingredients may be introduced into the environment separately or combined, whereas in the latter case it is possible to use a mixture of elements or compounds, as well as intermetallic compounds and alloys. Preferably, but not necessarily, the components are introduced into the process environment with mineralizer, or in other words a complex mineralizer is used, which in addition to the alkali metal contains also oxygen getter indicated above and acceptor dopant.

Preferably, the mineralizer contains sodium or potassium in a molar ratio to ammonia of from 0.005 to 0.5.

Particularly preferably, in the present invention stoichiometric gallium nitride—GaN is prepared.

Preferably, the method according to the invention the process is carried out in an autoclave with the capacity of higher than 600 cm³, more preferably higher than 9000 cm³.

The invention comprises also a monocrystalline gallium containing nitride, prepared with the above method, containing at least one element of Group I (IUPAC 1989) in an amount of at least 0.1 ppm, and containing oxygen in a concentration of not more than 1×10¹⁹ cm⁻³, preferably not more 5×10¹⁸ cm⁻³, and the most preferably not more than 1×10¹⁸ cm⁻³, which is characterized that it is a highly resistive (semi-insulating) material having a resistivity higher than 1×10⁶ Ωcm, more preferably higher than 1×10⁸ Ωcm, and preferably higher than 1×10¹⁰ Ωcm.

Preferably, according to the invention the nitride contains the acceptors selected from manganese, iron, vanadium or carbon, with a total concentration of not more than 1×10²¹ cm⁻³, more preferably not more than 1×10²⁰ cm⁻³, the most preferably not more than 1×10¹⁹ cm⁻³, wherein the ratio of oxygen concentration to the total concentration of acceptors is not smaller than 1.2.

Preferably, according to the invention the nitride is a stoichiometric gallium nitride GaN.

The gallium containing nitride is a chemical compound having in its structure at least gallium atom and a nitrogen atom. It is therefore at least a two-component compound of GaN, ternary compound of AlGaN, InGaN, and quaternary compound of AlInGaN, preferably containing a substantial amount of gallium at a level higher than the doped one. The composition of other elements with respect to gallium in the structure of the compound may be changed to a degree that does not interfere with the ammonium alkali nature of the crystallization technique.

The source material containing gallium is a gallium containing nitride or its precursor. As a source material it is possible to use a metallic gallium, GaN obtained by flux methods, HNP method, HVPE method, or the polycrystalline GaN obtained from metallic gallium as a result of the reaction in the supercritical ammonia solvent.

Mineralizer is a substance providing to the supercritical ammonia solvent one or more kinds of alkali metal ions, supporting the dissolution of the source material (as well as the gallium containing nitride).

Supercritical ammonia solvent is a supercritical solvent consisting of at least ammonia, which contains one or more kinds of alkali metal ions, supporting the dissolution of gallium containing nitride. Supercritical ammonia solvent may also contain derivatives of ammonia and/or mixtures thereof, in particular hydrazine.

### ADVANTAGEOUS EXAMPLES OF APPLYING THE INVENTION

### Example 1

### Obtaining Semi-Insulating GaN (Ca:NH₃=0.005; Mn:NH₃=0.00015; Na:NH₃=0.08)

The source material, i.e. 113.8 g (approx. 1.3 mol) of polycrystalline GaN containing 2.7 g of Ca (68 mmol) and 112 mg of Mn (2.05 mmol), was placed in a dissolution zone of a high pressure autoclave with a capacity of 600 cm³. 25.1 g (approx. 1.1 mol) of metallic sodium with 4N purity was also supplied to the autoclave.

18 plates of monocrystalline gallium nitride were used as seeds; they were obtained by HVPE or by crystallization from supercritical ammonia solution oriented perpendicularly to the c-axis of the monocrystal with a diameter of approx. 38 mm (1.5 inch) and thickness of about 1,000 μm each. The seeds were placed in the crystallization zone of the autoclave.

Next, the autoclave was filled with ammonia (5N) in the amount of 230 g (approx. 13.6 mol), closed and placed in a set of heaters.

The dissolution zone was heated (at the rate of approx. 0.5° C./min) up to 450° C. At that time the crystallization zone was not heated. After the predetermined temperature of 450° C. was reached in the dissolution zone (i.e. after approx. 15 hours from the beginning of the process), the temperature in the crystallization zone was about 170° C. Such a temperature distribution was maintained in the autoclave for 4 days. At that time the source material, i.e. polycrystalline GaN, was partially supplied to the solution. Next, the temperature in the crystallization zone was raised (at the rate of approx. 0.1° C./min) up to 550° C. while the temperature in the dissolution zone stayed unchanged. The pressure inside the autoclave was approx. 410 MPa. Such a temperature distribution resulted in convection between the zones in the autoclave and consequently—in chemical transport of gallium nitride from the dissolution zone (the upper one) to the crystallization zone (the bottom one), where it is deposited on the seeds. The distribution of temperature (i.e. 450° C. in the dissolution zone and 550° C. in the crystallization zone) was maintained for the next 56 days (until the end of the process).

As a result of the process the source material (i.e. polycrystalline GaN) was partially dissolved in the dissolution zone and monocrystalline gallium nitride grew on the seeds—(on every seed) about 1.75 mm (measured in the direction of c-axis of the monocrystal). This process produced a highly resistive (semi-insulating) material with a resistivity of 3×10⁸Ωcm. The concentration of oxygen measured by secondary ion mass spectrometry (SIMS) amounted to 2.5×10¹⁸cm⁻³ and the concentration Mn—2×10²⁰cm⁻³.

### Example 2

### Obtaining Doped GaN (Gd:NH₃=0.001; Mn:NH₃=0.000015; K:NH₃=0.04)

The source material, i.e. 1.4 kg (approx. 20.2 mol) of metallic Ga containing 31.76 g of Gd (0.2 mol) and 166 mg of Mn (3 mmol), was placed in a dissolution zone of a high pressure autoclave with a capacity of 9300 cm³. 316 g (approx. 8.1 mol) of metallic potassium with 4N purity was also supplied to the autoclave.

120 plates of monocrystalline gallium nitride were used as seeds; they were obtained by HVPE or by crystallization from supercritical ammonia solution oriented perpendicularly to the c-axis of the monocrystal with a diameter of approx. 38 mm (1.5 inch) and thickness of about 1,000 μm each. The seeds were placed in the crystallization zone of the autoclave.

Next, the autoclave was filled with ammonia (5N) in the amount of 3.44 kg (approx. 202 mol), closed and placed in a set of heaters.

The dissolution zone was heated (at the rate of approx. 0.5° C./min) up to 450° C. At that time the crystallization zone was not heated. After the predetermined temperature of 450° C. was reached in the dissolution zone (i.e. after approx. 15 hours from the beginning of the process), the temperature in the crystallization zone was about 170° C. Such a temperature distribution was maintained in the autoclave for 4 days. At that time gallium was partially supplied to the solution and undissolved gallium completely reacted to polycrystalline GaN. Next, the temperature in the crystallization zone was raised (at the rate of approx. 0.1° C./min) up to 550° C. while the temperature in the dissolution zone stayed unchanged. The pressure inside the autoclave was approx. 410 MPa. Such a temperature distribution resulted in convection between the zones in the autoclave and consequently—in chemical transport of gallium nitride from the dissolution zone (the upper one) to the crystallization zone (the bottom one), where it deposited on the seeds. The distribution of temperature (i.e. 450° C. in the dissolution zone and 550° C. in the crystallization zone) was maintained for the next 56 days (until the end of the process).

As a result of the process a layer of GaN was obtained (on every seed) with thickness of about 1.8 mm (measured in the direction of c-axis of the monocrystal). This process produced a highly resistive (semi-insulating) material with a resistivity of 8×10¹² Ωcm. The concentration of oxygen measured by secondary ion mass spectrometry (SIMS) amounted to 1.8×10¹⁸ cm⁻³ and the concentration of Mn—8×10¹⁸ cm⁻³.

### Example 3

### Obtaining Doped GaN (Y:NH₃=0.002; Mn:NH₃=0.00005; Na:NH₃=0.06)

The same procedure as in Example 2 except for the use of an autoclave with a capacity of 600 cm³; 94.8 g of metallic Ga (1.36 mol), 2.4 g of Y (approx. 0.27 mol), 37 mg of Mn (0.68 mmol), 18.8 g of Na (0.82 mol) were used as solid source substances.

The process resulted in obtaining (on every seed) a GaN layer with a thickness of about 1.6 mm (measured in the c-axis of the monocrystal). Highly resistive (semi-insulating) material was produced with a resistivity of 5×10¹¹ Ωcm. The concentration of oxygen measured by secondary ion mass spectroscopy (SIMS) was 2.1×10¹⁸ cm⁻³, the concentration of Mn—4×10¹⁹cm⁻³.

### Example 4

### Obtaining Doped GaN (Ca:NH₃=0.01; Fe:NH₃=0.004; K:NH₃=0.04)

The same procedure as in Example 1 except that the following were used as solid source substances: 113.8 g of polycrystalline GaN (1.36 mol), 5.4 g of Ca (approx. 137 mmol), 3.06 g of Fe (54.7 mmol), 21.4 g of K (0.55 mol).

The process resulted in obtaining (on every seed) a GaN layer with a thickness of about 1.6 mm (measured in the c-axis of the monocrystal). Highly resistive (semi-insulating) material was produced with a resistivity of 6×10⁹ Ωcm. The concentration of oxygen measured by secondary ion mass spectroscopy (SIMS) was 1.8×10¹⁸ cm⁻³, the concentration of Fe—8×10¹⁸cm⁻³.

### Example 5

### Obtaining Doped GaN (Gd:NH₃=0.001; Fe:NH₃=0.0005; Na:NH₃=0.1)

The same procedure as in Example 1 except that the following were used as solid source substances: 113.8 g of polycrystalline GaN (1.36 mol), 2.15 g of Gd (approx. 13.4 mmol), 0.38 g of Fe (6.8 mmol), 31.4 g of Na (1.4 mol).

The process resulted in obtaining (on every seed) a GaN layer with a thickness of about 1.6 mm (measured in the c-axis of the monocrystal). Highly resistive (semi-insulating) material was produced with a resistivity of 7×10¹⁰ Ωcm. The concentration of oxygen measured by secondary ion mass spectroscopy (SIMS) was 7×10¹⁷cm⁻³, the concentration of Fe—2×10¹⁸cm⁻³.

### Example 6

### Obtaining Doped GaN (Y:NH₃=0.004; V:NH₃=0.08; K:NH₃=0.1)

The same procedure as in Example 2 except for the use of an autoclave with a capacity of 600 cm³; 94.8 g of metallic Ga (1.36 mol), 4.9 g of Y (approx. 54.7 mmol), 55.8 g of mg V (1.1 mol), 53.4 g of K (1.3 mol) were used as solid source substances.

The process resulted in obtaining (on every seed) a GaN layer with a thickness of about 1.6 mm (measured in the c-axis of the monocrystal). Highly resistive (semi-insulating) material was produced with a resistivity of 5×10⁶ Ωcm. The concentration of oxygen measured by secondary ion mass spectroscopy (SIMS) was 1.7×10¹⁸ cm⁻³, the concentration of V—5×10¹⁸cm⁻³.

### Example 7

### Obtaining Doped GaN (Ca:NH₃=0.01; V:NH₃=0.0075; Na:NH₃=0.06)

The same procedure as in Example 1 except that the following were used as solid source substances: 113.8 g of polycrystalline GaN (1.36 mol), 5.4 g of Ca (approx. 137 mmol), 5.2 g of V (102 mmol), 18.9 g of Na (0.82 mol).

The process resulted in obtaining (on every seed) a GaN layer with a thickness of about 1.6 mm (measured in the c-axis of the monocrystal). Highly resistive (semi-insulating) material was produced with a resistivity of 2×10¹⁰ Ωcm. The concentration of oxygen measured by secondary ion mass spectroscopy (SIMS) was 1.5×10¹⁸ cm⁻³, the concentration of V—1×10¹⁸ cm⁻³.

### Example 8

### Obtaining Doped GaN (Gd:NH₃=0.002; C:NH₃=0.003, Na:NH₃=0.08).

The same procedure as in Example 1 except that the following were used as solid source substances: 113.8 g of polycrystalline GaN (1.36 mol), 4.3 g of Gd (approx. 27.3 mmol), 0.5 g of C (41 mmol), 25.1 g of Na (1.1 mol).

The process resulted in obtaining (on every seed) a GaN layer with a thickness of about 1.6 mm (measured in the c-axis of the monocrystal). Highly resistive (semi-insulating) material was produced with a resistivity of 4×10⁸ Ωcm. The concentration of oxygen measured by secondary ion mass spectroscopy (SIMS) was 1.3×10¹⁸ cm⁻³, the concentration of C—3×10¹⁹cm⁻³.

### Example 9

### Obtaining Doped GaN (Ca:NH₃=0.005; C:NH₃=0.0004, K:NH₃=0.1).

The same procedure as in Example 2 except for the use of an autoclave with a capacity of 600 cm³; 94.8 g of metallic Ga (1.36 mol), 2.7 g of Ca (approx. 68 mmol), 65 mg of C (5.5 mmol), 53.4 g of K (1.3 mol) were used as solid source substances.

The process resulted in obtaining (on every seed) a GaN layer with a thickness of about 1.6 mm (measured in the c-axis of the monocrystal). Highly resistive (semi-insulating) material was produced with a resistivity of 3×10¹¹Ωcm. The concentration of oxygen measured by secondary ion mass spectroscopy (SIMS) was 2×10¹⁸ cm⁻³, the concentration of C—9×10¹⁸cm⁻³.

13

1. The method for producing monocrystalline gallium containing nitride from a source material containing gallium in the environment of supercritical ammonia solvent with the addition of a mineralizer containing the element of Group I (IUPAC, 1989), wherein in an autoclave two temperature zones are generated, i.e. the dissolution zone with lower temperature containing the source material, and the crystallization zone located below it with higher temperature, containing at least one seed, the dissolution process of the source material and crystallization of gallium containing nitride on at least one seed is carried out, wherein
at least two further components are introduced into the process environment, namely:
a) the oxygen getter in the molar ratio to ammonia from 0.0001 to 0.2;
b) the acceptor dopants in the mole ratio to ammonia of not more than 0.1;
characterized in that the acceptor dopant constitutes manganese, iron, vanadium or carbon, or a combination thereof.

2. The method of claim. 1, characterized in that the acceptor dopant constitutes manganese in a molar ratio to ammonia from 0.000001 to 0.001, more preferably from 0.000005 to 0.0005, the most preferably from 0.00001 to 0.0001.

3. The method of claim. 1, characterized in that the acceptor dopant constitutes iron in a molar ratio to ammonia from 0.000001 to 0.01, more preferably from 0.00005 to 0.005, the most preferably from 0.0001 to 0.001.

4. The method of claim. 1, characterized in that the acceptor dopant constitutes vanadium in a molar ratio to ammonia from 0.000001 to 0.1, more preferably from 0.0005 to 0.05, the most preferably from 0.001 to 0.01.

5. The method of claim. 1, characterized in that the acceptor dopant constitutes carbon at a molar ratio to ammonia from 0.000001 to 0.1, more preferably from 0.00005 to 0.05, the most preferably from 0.0001 to 0.01.

6. A method according to any of the preceding claims, characterized in that the oxygen getter constitutes calcium or a rare-earth element, preferably gadolinium or yttrium, or a combination thereof.

7. A method according to any of the preceding claims, characterized in that the oxygen getter and acceptor dopant is introduced in the elemental form, i.e. metal or as a compound, preferably from the group comprising azides, amides, imides, amide-imides and hydrides, wherein the components are introduced separately or combined, in the case of combined introduction, mixtures of elements and compounds, intermetallic compounds or alloys are used.

8. A method according to any of the preceding claims, characterized in that the oxygen getter and/or acceptor dopant is introduced into the process environment with mineralizer.

9. A method according to any of the preceding claims, characterized in that the mineralizer contains sodium or potassium in a molar ratio to ammonia of from 0.005 to 0.5.

10. A method according to any of the preceding claims, characterized in that the stoichiometric gallium nitride—GaN is produced.

11. A method according to any of the preceding claims, characterized in that it is carried out in an autoclave having a capacity of more than 600 cm³, more preferably greater than 9000 cm³.

12. The monocrystalline gallium containing nitride, prepared with the method according to any of the preceding claims, comprising at least one element of Group I (IUPAC 1989) in an amount of at least 0.1 ppm, and contains oxygen in a concentration of not more than 1×10¹⁹ cm⁻³, preferably not more 5×10¹⁸ cm⁻³, and the most preferably not more than 1×10¹⁸ cm⁻³, characterized in that it is a highly resistive (semi-insulating) material having the resistivity greater than 1×10⁶ Ωcm, preferably greater than 1×10⁸ Ωcm and the most preferably greater than 1×10¹⁰ Ωcm.

13. The nitride according to claim 12, characterized in that it contains the acceptors selected from manganese, iron, vanadium or carbon, with a total concentration of not more than 1×10²¹ cm ³, more preferably not more than 1×10²⁰ cm ³, the most preferably not more than 1×10¹⁹ cm⁻³, wherein the ratio of oxygen concentration to the total concentration of acceptors is not smaller than 1.2.

14. A nitride claim 12 or 13, characterized in that it is a stoichiometric gallium nitride GaN.
